(19) United States
(12) Patent Application Publication
(10) Pub. No.: US 2025/0123313 A1
(43) Pub. Date: Apr. 17, 2025

(54) SYSTEMS AND METHODS FOR DUTY CYCLE CHARACTERIZATION

(71) Applicant: Taiwan Semiconductor Manufacturing Company, Ltd., Hsinchu (TW)

(72) Inventors: Chung-Ting LU, Kaohsiung City (TW); Shu-Chin TAI, Hsinchu (TW); Yung-Chow PENG, Hsinchu (TW)

(21) Appl. No.: 18/485,001

(22) Filed: Oct. 11, 2023

(51) Int. Cl. G01R 29/02; G01R 31/28; H03K 7/08; H03K 19/20

(52) U.S. Cl. CPC G01R 29/02; G01R 31/2851; H03K 7/08; H03K 19/20

(57) ABSTRACT

A method includes coupling a first signal to an impedance; determining a first average current of the first signal through the impedance over a first time, the first average current corresponding to a duty cycle of the first signal; coupling a second signal to the impedance; determining a second average current of the second signal through the impedance over a second time, the second average current corresponding to a first duty cycle of the second signal; determining the first duty cycle from the first average current and the second average current; determining a third average current of the second signal through the impedance over a third time, the third average current corresponding to a second duty cycle of the second signal; determining the second duty cycle from the first average current and the third average current; and averaging the first duty cycle and the second duty cycle.

### BACKGROUND

Often, electronic circuits are used to measure timing quantities, such as jitter, duty cycle, pulse width, frequency, signal delays, and between signal timing. These electronic circuits usually include at least one integrated circuit (IC) that is manufactured in a semiconductor process. Typically, one or more timing measurement circuits are included in the electronic circuit for performing the timing measurements. The timing measurement circuits are complex circuits that use significant silicon area. Also, calibration of the timing measurement circuits increases the cost of having and operating the electronic circuit.

Usually, duty cycle characterization is important in electronic circuits that include built-in self-test (BIST) and/or level shifters. In addition, high-speed duty cycle characterization is needed and more challenging than slow-speed duty cycle characterization.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion. In addition, the drawings are illustrative as examples of embodiments of the disclosure and are not intended to be limiting.

FIG. 1 is a diagram schematically illustrating a resistor configured to receive an input signal IN and a current meter configured to measure the output current Iout that flows through the resistor, in accordance with some embodiments.

FIG. 2 is a diagram schematically illustrating the DC input signal and the DC output current Idc, in accordance with some embodiments.

FIG. 3 is a diagram schematically illustrating the average output current Ix through the resistor due to the periodic signal, in accordance with some embodiments.

FIG. 4 is a diagram schematically illustrating the periodic signal with a non-linear fall time that results in errors in the duty cycle characterization, in accordance with some embodiments.

FIG. 5 is a diagram schematically illustrating that as the frequency of a periodic signal increases, the non-linear rise and fall times become a larger portion of the periodic signal, in accordance with some embodiments.

FIG. 6 is a diagram schematically illustrating a first circuit for determining the first duty cycle that is based on the interval of time that the periodic signal is at a high voltage, in accordance with some embodiments.

FIG. 7 is a diagram schematically illustrating a periodic signal with non-linear rise and fall times that favor the “1” region and an average output current Ia, in accordance with some embodiments.

FIG. 8 is a diagram schematically illustrating a second circuit for determining the second duty cycle of the periodic signal, which is based on the interval of time that the periodic signal is at a low voltage, in accordance with some embodiments.

FIG. 9 is a diagram schematically illustrating the periodic signal with the non-linear rise and fall times unfavorable to the “0” region and an average output current Ib, in accordance with some embodiments.

FIG. 10 is a diagram schematically illustrating a system for duty cycle characterization, in accordance with some embodiments.

FIG. 11 is a diagram schematically illustrating the logic circuit, in accordance with some embodiments.

FIG. 12 is a diagram schematically illustrating the measurement circuit, in accordance with some embodiments.

FIG. 13 is a diagram schematically illustrating error percentages in TCC duty cycle measurements of the first duty cycle of a periodic signal, in accordance with some embodiments.

FIG. 14 is a diagram schematically illustrating the error percentages of Error_TCC vs Out versus the frequency of the periodic input signal IN, in accordance with some embodiments.

FIG. 15 is a diagram schematically illustrating error percentages in TCC duty cycle measurements of the first duty cycle of a periodic signal and error percentages in TCC duty cycle measurements of the second duty cycle of the periodic signal, in accordance with some embodiments.

FIG. 16 is a diagram schematically illustrating averaging the first duty cycle measurement and the second duty cycle measurement to obtain an average duty cycle that has an error percentage closer to 0%, in accordance with some embodiments.

FIG. 17 is a diagram schematically illustrating error percentages in TCC duty cycle measurements of a periodic signal that has a 40% duty cycle, in accordance with some embodiments.

FIG. 18 is a diagram schematically illustrating averaging the first duty cycle measurement and the second duty cycle measurement to obtain an average duty cycle that has an error percentage closer to 0%, in accordance with some embodiments.

FIG. 19 is a diagram schematically illustrating a method of obtaining an average duty cycle measurement, in accordance with some embodiments.

FIG. 20 is a diagram schematically illustrating another method of obtaining an average duty cycle measurement, in accordance with some embodiments.

FIG. 21 is a block diagram schematically illustrating an example of a computer system configured to provide the semiconductor devices of the current disclosure, in accordance with some embodiments.

FIG. 22 is a block diagram of a semiconductor device manufacturing system and a semiconductor device manufacturing flow associated therewith, in accordance with some embodiments.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

In some electronic circuits, such as transmit/receive (TX/RX) post-driver circuits and high-speed ring oscillators (ROs), duty cycle characterization is a key specification. As described herein, based on energy conservation concepts, an interval of time, such as the interval of time that a periodic signal is high, can be converted to a current using a time to current conversion (TCC) circuit. The duty cycle of the periodic signal, i.e., the percentage of time that the periodic signal is high, can be determined based on this current measurement and a current measurement of another signal with a known duty cycle. For example, the duty cycle of a periodic signal, such as a clock signal, can be determined from a ratio of the average current of the periodic signal through an impedance divided by the average current of a direct current (DC) current through the impedance. Each of the signals passes through the impedance, such as a resistor, and the ratio of the average current due to the periodic signal divided by the DC current is the duty cycle, which can be divided by frequency, i.e., multiplied by the period of the periodic signal, to provide the time that the periodic signal is high. This duty cycle characterization of a low-speed clock signal provides a low error, such as 0.02% at 100 mega-Hertz (MHz). However, this type of duty cycle characterization of a high-speed clock signal provides a higher error, such as 2% at 10 giga-Hertz (GHz). The TCC method is described in U.S. Pat. No. 8,664,978, titled “Methods and Apparatus for Time to Current Conversion” issued Mar. 4, 2014, which is hereby incorporated by reference in its entirety.

The errors in duty cycle measurement are at least partly due to non-linear rise and fall times that result in errors in the TCC. Also, as frequencies increase, the weighting of the non-linear rise and fall times increases. To improve the accuracy of the duty cycle measurements, a first duty cycle is determined based on the interval of time that the periodic signal is high, and a second duty cycle is determined based on the interval of time that the periodic signal is low. The first duty cycle and the second duty cycle are averaged to provide a more accurate duty cycle measurement of the periodic signal.

For example, if the non-linear portion of the periodic signal is more favorable to the high or “1” region and less favorable to the low or “0” region, then averaging the duty cycles from the two regions provides a more accurate duty cycle characterization, such as close to 0%.

Disclosed embodiments provide a method that includes coupling a first signal to an impedance; determining a first average current of the first signal through the impedance over a first time, the first average current corresponding to a duty cycle of the first signal; coupling a second signal to the impedance; determining a second average current of the second signal through the impedance over a second time, the second average current corresponding to a first duty cycle of the second signal; determining the first duty cycle from the first average current and the second average current; determining a third average current of the second signal through the impedance over a third time, the third average current corresponding to a second duty cycle of the second signal; determining the second duty cycle from the first average current and the third average current; and averaging the first duty cycle and the second duty cycle to obtain an average duty cycle of the second signal.

Further disclosed embodiments provide a system that includes a logic circuit, an impedance, and a measurement circuit. The logic circuit has at least one input configured to receive a first signal and a second signal and an output configured to provide a first output signal that corresponds to the first signal and a second output signal that corresponds to the second signal. The impedance is connected to the output and configured to receive the first output signal and the second output signal. The measurement circuit is connected to the impedance and configured to determine a first average current through the impedance based on the first output signal, a second average current through the impedance to a reference voltage based on the second signal, and a third average current through the impedance from a power source based on the second signal.

Still further disclosed embodiments include the measurement circuit configured to determine a first duty cycle of the second signal from the first average current and the second average current, a second duty cycle of the second signal from the first average current and the third average current, and a duty cycle of the second signal based on an average of the first duty cycle and the second duty cycle.

Advantages of the methods and systems disclosed herein include improved accuracy of the duty cycle measurement and speed in determining the duty cycle.

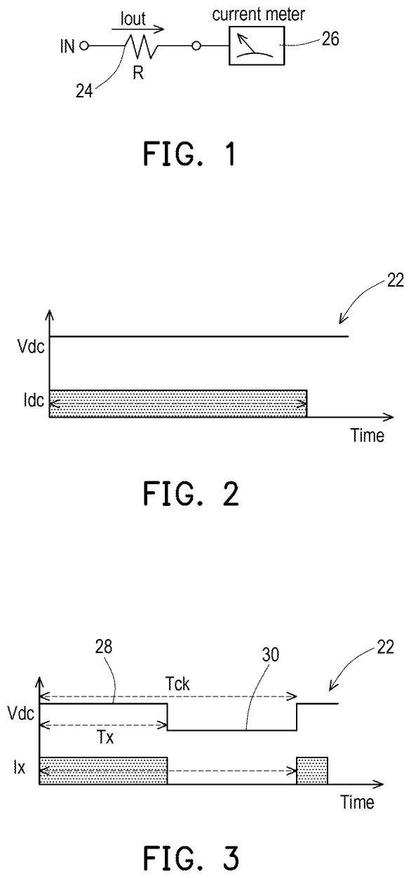

FIGS. 1-3 are diagrams schematically illustrating a TCC technique for duty cycle characterization of a periodic signal 20, in accordance with some embodiments. The periodic signal 20 is converted to a current during the time Tx that the periodic signal 20 is a high voltage to provide an average output current Ix over the clock period Tck of the periodic signal 20. The duty cycle of the periodic signal 20, i.e., the percentage of time that the periodic signal 20 is a high voltage, is determined based on the average output current Ix divided by a DC output current Idc for a DC input signal 22 over the clock period Tck.

FIG. 1 is a diagram schematically illustrating a resistor 24 configured to receive an input signal IN and a current meter 26 configured to measure the output current Iout that flows through the resistor 24, in accordance with some embodiments. The resistor 24 is connected to the current meter 26. The resistor 24 receives the input signal IN and provides the output current Iout to the current meter 26. The resistor 24 can be any suitable resistance value.

FIG. 2 is a diagram schematically illustrating the DC input signal 22 and the DC output current Idc, in accordance with some embodiments. The DC input signal 22 is provided to the resistor 24 with the DC input signal 22 having a voltage of Vdc. Current passes through the resistor 24 to provide the DC output current Idc that, in some embodiments, is an average DC current through the resistor 24 over the clock period Tck of the periodic signal 20.

FIG. 3 is a diagram schematically illustrating the average output current Ix through the resistor 24 due to the periodic signal 20, in accordance with some embodiments. The periodic signal 20 is provided as the input signal IN, with the periodic signal 20 having a high voltage portion 28 at voltage Vdc and a low voltage portion 30 at 0 volts. Current passes through the resistor 24 during the high voltage portion 28, but not during the low voltage portion 30. The current passing through the resistor 24 during the high voltage portion 28 is averaged over the clock period Tck of the periodic signal 20 to provide the average output current Ix.

The duty cycle of the periodic signal 20 is determined by dividing the average output current Ix by the DC output current Idc, such that the ratio of the average output current Ix to the DC output current Idc is the duty cycle. In some embodiments, this ratio is divided by the frequency of the periodic signal 20, i.e., multiplied by the clock period Tck of the periodic signal 20, to provide the time Tx that the periodic signal 20 is high.

This duty cycle characterization of a low-speed clock signal provides a low error, such as 0.02% at 100 MHz, while this duty cycle characterization of a high-speed clock signal provides a higher error, such as 2% at 10 GHz.

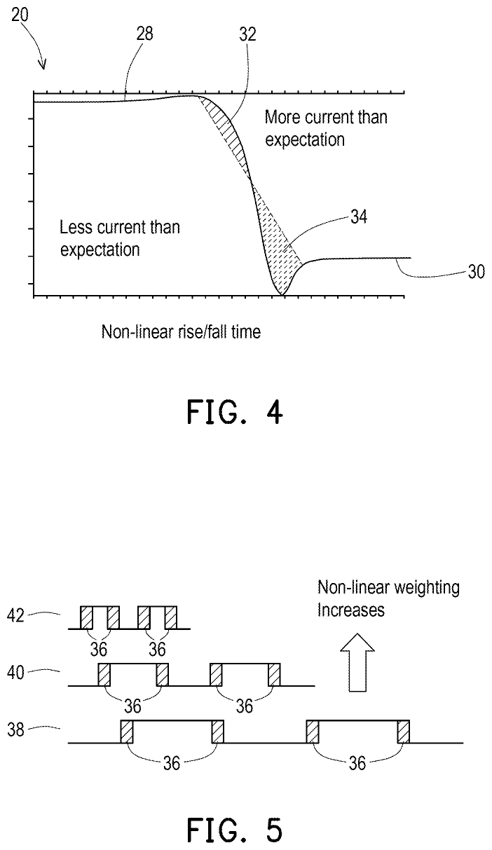

FIG. 4 is a diagram schematically illustrating the periodic signal 20 with a non-linear fall time that results in errors in the duty cycle characterization, in accordance with some embodiments. The non-linear rise and fall times result in more current than expected or less current than expected during the high voltage portion 28 and the low voltage portion 30 of the periodic signal 20. Also, whether the non-linearity favors more current or less current is difficult to predict.

As illustrated in FIG. 4, the periodic signal 20 includes a first portion 32 that provides more current than expected during the high voltage portion 28 and a second portion 34 that provides less current than expected during the low voltage portion 30. This introduces error into the duty cycle characterization described above.

FIG. 5 is a diagram schematically illustrating that as the frequency of a periodic signal increases, the non-linear rise and fall times 36 become a larger portion of the periodic signal, in accordance with some embodiments. In the periodic signal 38, the non-linear rise and fall times 36 are a smaller portion of the periodic signal 38 than in the periodic signal 40. Also, in the periodic signal 40, the non-linear rise and fall times 36 are a smaller portion of the periodic signal 40 than in the periodic signal 42.

Thus, as the frequency of the periodic signal increases, the weighting of the non-linear rise and fall times 36 increases, which increases the error introduced into the duty cycle characterization.

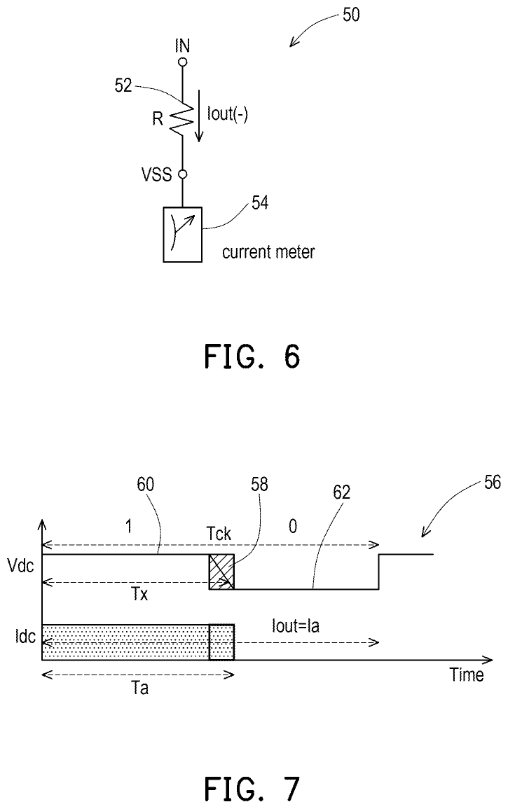

FIGS. 6-9 are diagrams schematically illustrating methods and systems for duty cycle characterization that improves the accuracy of the duty cycle measurements, in accordance with some embodiments. To improve the accuracy of the duty cycle measurements, a first duty cycle is determined based on the interval of time that the periodic signal is at a high voltage, and a second duty cycle is determined based on the interval of time that the periodic signal is at a low voltage. The first duty cycle measurement and the second duty cycle measurement are averaged to provide a more accurate duty cycle measurement of the periodic signal.

For example, if the non-linear rise and fall times of the periodic signal are more favorable to the high voltage or “1” region and less favorable to the low voltage or “0” region, then the first duty cycle measurement is skewed in one direction and the second duty cycle measurement is skewed in the other direction, such that averaging the first duty cycle measurement and the second duty cycle measurement provides a duty cycle measurement that has an error closer to 0% than either one of the first duty cycle measurement and the second duty cycle measurement.

FIG. 6 is a diagram schematically illustrating a first circuit 50 for determining the first duty cycle that is based on the interval of time that the periodic signal is at a high voltage, in accordance with some embodiments. The first circuit 50 includes a resistor 52 connected to a current meter 54. One end of the resistor 52 receives an input signal IN and another end of the resistor 52 receives a reference voltage VSS. An output current Iout flows through the resistor 52, from the input signal IN to the reference voltage VSS and the current meter 54 measures the output current Iout, where the absolute value of the output current Iout is used to determine the first duty cycle. The resistor 52 can be any suitable resistance value.

FIG. 7 is a diagram schematically illustrating a periodic signal 56 with non-linear rise and fall times 58 that favor the “1” region and an average output current Ia, in accordance with some embodiments. The periodic signal 56 is provided as the input signal IN, with the periodic signal 56 having a high voltage portion 60 at voltage Vdc and a low voltage portion 62 at 0 volts. The output current Iout passes through the resistor 52 from the periodic signal 56 to the reference voltage VSS during the high voltage portion 60, but not during the low voltage portion 62. The current passing through the resistor 52 during the high voltage portion 60 is averaged over the clock period Tck of the periodic signal 56 to provide the average output current Ia over the clock period Tck.

The first duty cycle of the periodic signal 56, which is based on the high voltage or “1” region, is determined by dividing the average output current Ia by a DC output current Idc that passes through the resistor 52. The ratio of the average output current Ia to the DC output current Idc is the duty cycle. In some embodiments, this ratio is divided by the frequency of the periodic signal 56, i.e., multiplied by the clock period Tck of the periodic signal 56, to provide the time Tx that the periodic signal 56 is high. As illustrated in FIG. 7, the non-linear rise and fall times 58 are favorable to the “1” region, which introduces error into the first duty cycle measurement that is based on the “1” region.

In other examples, the non-liner rise and fall times 58 may be favorable or non-favorable to the “1” region. If the non-linear rise and fall times 58 are favorable to the “1” region, then the non-linear rise and fall times 58 are unfavorable to the “0” region. Also, if the non-linear rise and fall times 58 are unfavorable to the “1” region, then the non-linear rise and fall times 58 are favorable to the “0” region.

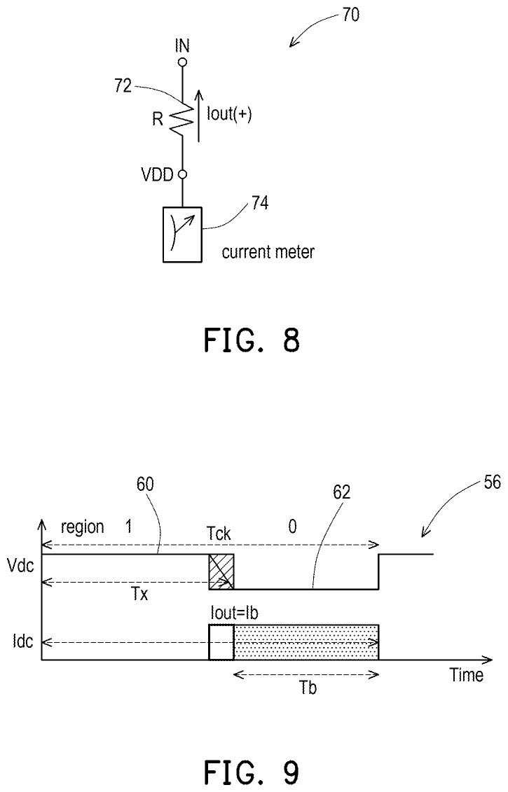

FIG. 8 is a diagram schematically illustrating a second circuit 70 for determining the second duty cycle of the periodic signal 56, which is based on the interval of time that the periodic signal 56 is at a low voltage, in accordance with some embodiments. The second circuit 70 includes a resistor 72 connected to a current meter 74. One end of the resistor 72 receives an input signal IN and another end of the resistor 72 receives a power voltage VDD. An output current Iout flows through the resistor 72, from the power voltage VDD to the input signal IN. The current meter 74 measures the output current Iout, where the absolute value of the output current Iout is used to determine the second duty cycle. The resistor 72 can be any suitable resistance value. In some embodiments, the resistor 72 is the same as the resistor 52.

FIG. 9 is a diagram schematically illustrating the periodic signal 56 with the non-linear rise and fall times 58 unfavorable to the “0” region and an average output current Ib, in accordance with some embodiments. The periodic signal 56 is provided as the input signal IN, with the periodic signal 56 having the high voltage portion 60 at voltage Vdc and the low voltage portion 62 at 0 volts. The output current Iout passes through the resistor 72 from the power voltage VDD to the periodic signal 56 during the low voltage portion 62, but not during the high voltage portion 60. The current passing through the resistor 72 during the low voltage portion 62 is averaged over the clock period Tck of the periodic signal 56 to provide the average output current Ib.

The second duty cycle of the periodic signal 56, which is based on the low voltage or “0” region, is determined by dividing the average output current Ib by a DC output current Idc that passes through the resistor 72. This provides a ratio of the average output current Ib to the DC output current Idc. This ratio is subtracted from 1 to obtain the second duty cycle, i.e., the percentage of time that the periodic signal 56 is at a high voltage. In some embodiments, the ratio is divided by the frequency of the periodic signal 56, i.e., multiplied by the clock period Tck of the periodic signal 56, to provide the time Tb that the periodic signal 56 is at the low voltage. In some embodiments, the duty cycle percentage is divided by the frequency of the periodic signal 56, i.e., multiplied by the clock period Tck of the periodic signal 56, to provide a second time Ta that the periodic signal 56 is at the high voltage. As illustrated in FIG. 9, the non-linear rise and fall times 58 are unfavorable to the “0” region, which introduces error into the second duty cycle measurement that is based on the “0” region.

The first duty cycle measurement and the second duty cycle measurement are averaged to provide the more accurate duty cycle measurement of the periodic signal 56.

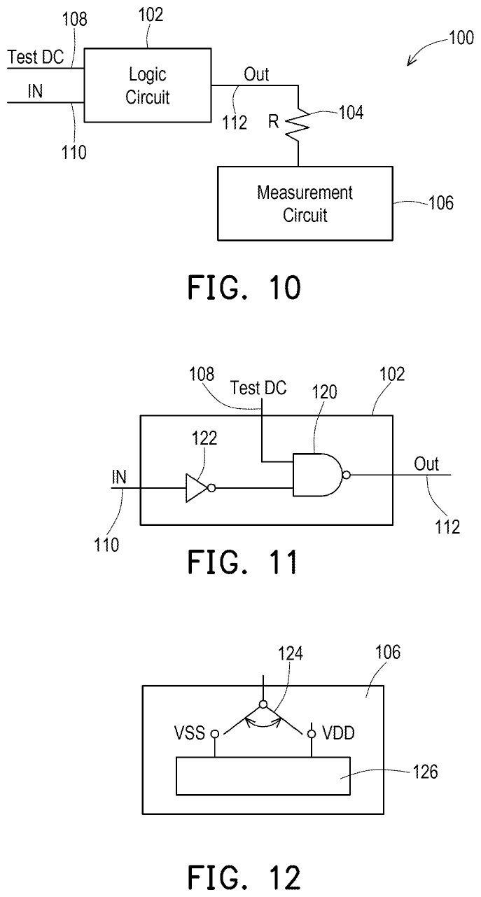

FIG. 10 is a diagram schematically illustrating a system 100 for duty cycle characterization, in accordance with some embodiments. The system 100 includes a logic circuit 102, an impedance 104, and a measurement circuit 106. The logic circuit 102 is electrically connected to the impedance 104 that is electrically connected to the measurement circuit 106.

The logic circuit 102 has a first input 108, a second input 110, and an output 112. The first input 108 receives a Test DC signal, the second input 110 receives an input signal IN, and the output 112 provides an output signal Out to the impedance 104.

If the Test DC signal is a low voltage, the logic circuit 102 provides a high voltage, such as power voltage VDD, at the output 112. With the output 112 at the power voltage VDD, the current through the impedance 104 is the output current Idc.

If the Test DC signal is at a high voltage, the output 112 follows the input signal IN, such as a periodic signal, that is provided at the second input 110. The output signal Out is provided to the impedance 104 for duty cycle characterization, including determination of the first duty cycle of the periodic signal and the second duty cycle of the periodic signal, as described above.

The impedance 104 is connected to the output 112 of the logic circuit 102 and configured to receive the power voltage VDD and the periodic signal in the output signal Out. In some embodiments, the impedance 104 is a resistor R.

The measurement circuit 106 is connected to the impedance 104 and configured to determine the output current Idc that flows through the impedance 104 in response to the Test DC signal being at a low voltage and the output 112 being at the DC power voltage VDD. Also, the measurement circuit 106 is configured to determine a first average output current Iout1 over the clock period Tck of the periodic signal, which is based on the current that flows through the impedance 104 from the high voltage portion of the periodic signal to the reference voltage VSS. In addition, the measurement circuit 106 is configured to determine a second average output current Iout2 over the clock period Tck of the periodic signal, which is based on the current that flows through the impedance 104 from a power voltage VDD to the low voltage portion of the periodic signal.

Also, the measurement circuit 106 is configured to determine the first duty cycle of the periodic signal from the first average output current Iout1 and the DC output current Idc, the second duty cycle of the periodic signal from the second average output current Iout2 and the DC output current Idc, and an average duty cycle of the periodic signal based on an average of the first duty cycle and the second duty cycle.

In some embodiments, the measurement circuit 106 is configured to determine the first duty cycle from the first average output current Iout1 and the DC output current Idc by dividing the first average output current Iout1 by the DC output current Idc. In some embodiments, the measurement circuit 106 is configured to determine the second duty cycle from the second average output current Iout2 and the DC output current Idc by dividing the second average output current Iout2 by the DC output current Idc to obtain a first result and subtracting the first result from one (1) to obtain the second duty cycle.

FIG. 11 is a diagram schematically illustrating the logic circuit 102, in accordance with some embodiments. The logic circuit 102 includes a NAND gate 120 and an inverter 122. The first input 108 is connected to one input of the NAND gate 120 and the second input 110 is connected to the input of the inverter 122. The output of the inverter 122 is connected to another input of the NAND gate 120, and the output of the NAND gate 120 provides the output signal Out at the output 112.

In operation, if the Test DC signal is a low voltage, the NAND gate 120 provides a high voltage, such as power voltage VDD, at the output 112. Also, if the Test DC signal is a high voltage, the output 112 follows the input signal IN, where the inverter 122 inverts the input signal IN and the NAND gate 120 inverts the output of the inverter 122 to follow the input signal IN at the output 112.

FIG. 12 is a diagram schematically illustrating the measurement circuit 106, in accordance with some embodiments. The measurement circuit 106 includes a switch 124 and a current measurement and duty cycle determination circuit 126. The switch 124 is connected to the impedance 104 and configured to switch between the reference voltage VSS and the power voltage VDD to measure the current through the impedance during the high voltage portion and the low voltage portion of the periodic signal, respectively. The current measurement and duty cycle determination circuit 126 is configured to perform the functions of duty cycle characterization as described herein.

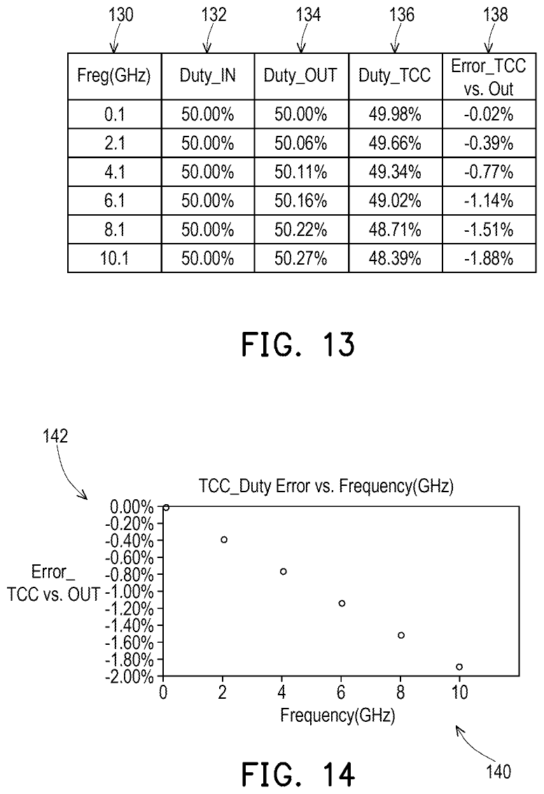

FIG. 13 is a diagram schematically illustrating error percentages in TCC duty cycle measurements of the first duty cycle of a periodic signal, in accordance with some embodiments. The first duty cycle measurement is based on only the high voltage portion of the periodic signal.

In this example, system 100 of FIG. 10 is used to make the duty cycle measurements. The logic circuit 102 receives a high voltage in the input signal Test DC at the first input 108 and a periodic input signal IN at the second input 110. The logic circuit 102 provides a periodic output signal Out at the output 112, which follows the periodic input signal IN. The output signal Out passes through the impedance 104 to the reference signal VSS and the measurement circuit 106 to obtain the first duty cycle measurement.

The duty cycle measurements of the periodic signal are taken at different frequencies Freq 130 of the periodic signal. These frequencies Freq 130 range from 0.1 GHz to 10.1 GHz and the duty cycle Duty_IN 132 of each of the periodic input signals IN is 50%.

The duty cycle Duty_OUT 134 is the duty cycle of the periodic output signal Out at the output 112. The duty cycle Duty_OUT 134 increases from 50% at 0.1 GHz to 50.27% at 10.1 GHz. Also, the duty cycle Duty_TCC 136 is the duty cycle of the periodic signal measured at the measurement circuit 106 and the reference voltage VSS. The duty cycle Duty_TCC 136 decreases from 49.98% at 0.1 GHz to 48.39% at 10.1 GHz. This results in error percentages in the TCC duty cycle measurements from the duty cycle Duty_OUT 134 to the duty cycle Duty_TCC 136 of Error_TCC vs Out 138 that range from −0.02% at 0.1 GHz to −1.88% at 10.1 GHZ, increasing negatively with the increase in the frequency Freq 130 of the periodic input signal IN.

FIG. 14 is a diagram schematically illustrating the error percentages of Error_TCC vs Out 138 versus the frequency of the periodic input signal IN, in accordance with some embodiments. The frequency is graphed along the x-axis 140 and the Error_TCC vs Out 138 is graphed along the y-axis 142. The error percentages of Error_TCC vs Out 138 range from −0.02% at 0.1 GHz to −1.88% at 10.1 GHZ, increasing negatively with the increase in frequency Freq 130.

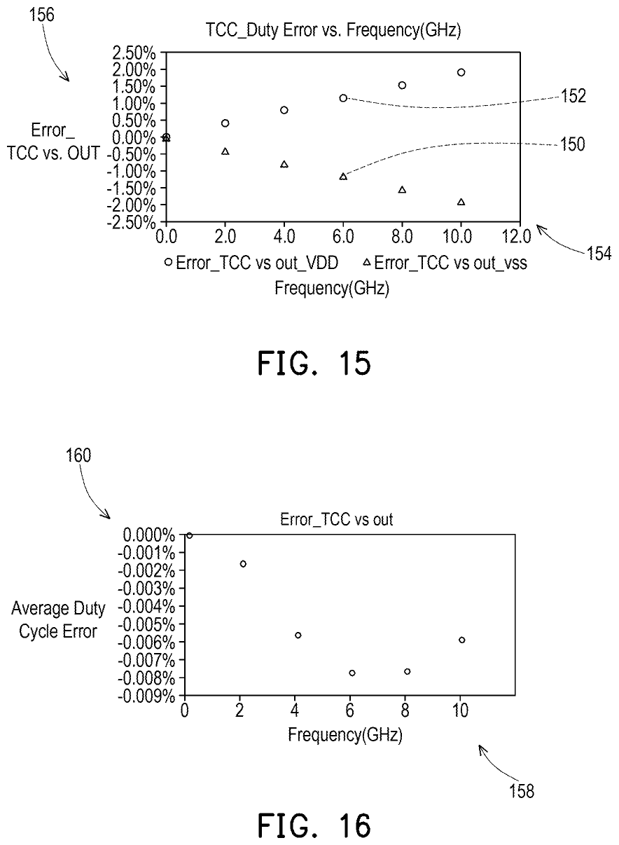

FIG. 15 is a diagram schematically illustrating error percentages in TCC duty cycle measurements of the first duty cycle 150 of a periodic signal and error percentages in TCC duty cycle measurements of the second duty cycle 152 of the periodic signal, in accordance with some embodiments. The first duty cycle measurements are based on only the high voltage portion of the periodic signal, and the second duty cycle measurements are based on only the low voltage portion of the periodic signal. The frequency of the periodic signal is graphed along the x-axis 154 and the Error_TCC vs Out is graphed along the y-axis 156.

In this example, system 100 of FIG. 10 is used to make the duty cycle measurements. The logic circuit 102 receives a high voltage in the input signal Test DC at the first input 108 and a periodic input signal IN at the second input 110. The logic circuit 102 provides a periodic output signal Out at the output 112, which follows the periodic input signal IN. In the first duty cycle measurement, current flows from the output 112 during the high voltage portion of the periodic output signal Out through the impedance 104 to the reference signal VSS and the measurement circuit 106 to obtain the first duty cycle measurement. In the second duty cycle measurement, current flows from the power signal VDD and the measurement circuit 106 through the impedance 104 to the output 112 during the low voltage portion of the periodic output signal Out to obtain the second duty cycle measurement.

The error percentages Error_TCC vs Out in the duty cycle measurements of the first duty cycle increase negatively with the increase in frequency 154, and the error percentages Error_TCC vs Out in the duty cycle measurements of the second duty cycle increase positively with the increase in frequency 154.

FIG. 16 is a diagram schematically illustrating averaging the first duty cycle measurement and the second duty cycle measurement to obtain an average duty cycle that has an error percentage closer to 0%, in accordance with some embodiments. The frequency of the periodic signal is graphed along the x-axis 158 and the Average Duty Cycle Error is graphed along the y-axis 160.

The measurement circuit 106 determines the first duty cycle of the periodic signal and the second duty cycle of the periodic signal. The measurement circuit then determines the average duty cycle of the periodic signal, which reduces the error percentage of the duty cycle measurement at each of the different frequencies 158.

Averaging the first duty cycle measurement and the second duty cycle measurement results in an average duty cycle measurement, where the negative error percentage of the first duty cycle measurement is offset by the positive error percentage of the second duty cycle measurement. This results in a duty cycle measurement that has an error percentage closer to 0%.

FIG. 17 is a diagram schematically illustrating error percentages in TCC duty cycle measurements of a periodic signal that has a 40% duty cycle, in accordance with some embodiments. The error percentages in the TCC duty cycle measurements include the first duty cycle 170 of the periodic signal and the second duty cycle 172 of the periodic signal. The first duty cycle measurements are based on the high voltage portion of the periodic signal, and the second duty cycle measurements are based on the low voltage portion of the periodic signal. The frequency of the periodic signal is graphed along the x-axis 174 and the Error_TCC vs Out is graphed along the y-axis 176.

In this example, system 100 of FIG. 10 is used to make the duty cycle measurements. The logic circuit 102 receives a high voltage in the input signal Test DC at the first input 108 and a periodic input signal IN at the second input 110. The logic circuit 102 provides a periodic output signal Out at the output 112, which follows the periodic input signal IN. In the first duty cycle measurement, current flows from the output 112 during the high voltage portion of the periodic output signal Out through the impedance 104 to the reference signal VSS and the measurement circuit 106 to obtain the first duty cycle measurement. In the second duty cycle measurement, current flows from the power signal VDD and the measurement circuit 106 through the impedance 104 to the output 112 during the low voltage portion of the periodic output signal Out to obtain the second duty cycle measurement.

The error percentages Error_TCC vs Out in the duty cycle measurements of the first duty cycle increase negatively with the increase in frequency 174, and the error percentages Error_TCC vs Out in the duty cycle measurements of the second duty cycle increase positively with the increase in frequency 174.

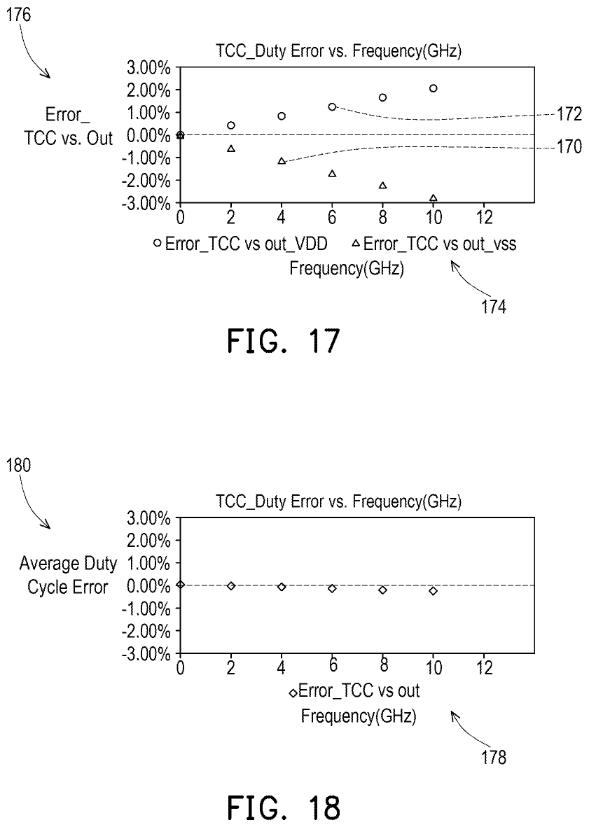

FIG. 18 is a diagram schematically illustrating averaging the first duty cycle measurement and the second duty cycle measurement to obtain an average duty cycle that has an error percentage closer to 0%, in accordance with some embodiments. The frequency of the periodic signal is graphed along the x-axis 178 and the Average Duty Cycle Error is graphed along the y-axis 180.

The measurement circuit 106 determines the first duty cycle of the periodic signal and the second duty cycle of the periodic signal. The measurement circuit then determines the average duty cycle of the periodic signal, which reduces the error percentage of the duty cycle measurement at each of the different frequencies 178.

Averaging the first duty cycle measurement and the second duty cycle measurement results in an average duty cycle measurement, where the negative error percentage of the first duty cycle measurement is offset by the positive error percentage of the second duty cycle measurement. This results in a duty cycle measurement that has an error percentage closer to 0%.

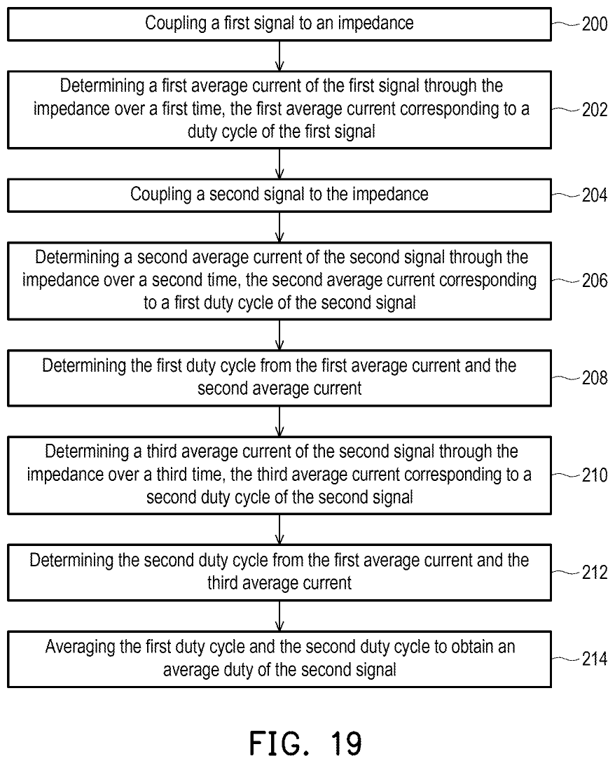

FIG. 19 is a diagram schematically illustrating a method of obtaining an average duty cycle measurement, in accordance with some embodiments. At 200, the method includes coupling a first signal to an impedance and, at 202, the method includes determining a first average current of the first signal through the impedance over a first time. The first average current corresponds to a duty cycle of the first signal. In some embodiments, coupling the first signal to the impedance includes coupling a DC signal to the impedance.

At 204, the method includes coupling a second signal to the impedance. In some embodiments, coupling the second signal to the impedance includes coupling a periodic signal to the impedance.

At 206, the method includes determining a second average current of the second signal through the impedance over a second time. The second average current corresponds to a first duty cycle of the second signal. In some embodiments, determining the second average current of the second signal through the impedance includes determining the second average current of the second signal through the impedance to a reference voltage VSS over the second time.

At 208, the method includes determining the first duty cycle from the first average current and the second average current. In some embodiments, determining the first duty cycle from the first average current and the second average current includes dividing the second average current by the first average current. In some embodiments, determining the first duty cycle from the first average current and the second average current includes dividing the second average current by the first average current to obtain a current ratio and multiplying the current ratio by a cycle period of the periodic signal.

At 210, the method includes determining a third average current of the second signal through the impedance over a third time. The third average current corresponds to a second duty cycle of the second signal. In some embodiments, determining the third average current of the second signal through the impedance includes determining the third average current of the second signal through the impedance from a power source VDD over the third time. In some embodiments, the first time is equal to each of the second time and the third time. In some embodiments, the second time is equal to the third time.

At 212, the method includes determining the second duty cycle from the first average current and the third average current. In some embodiments, determining the second duty cycle from the first average current and the third average current includes dividing the third average current by the first average current to obtain a first result and subtracting the first result from one to obtain a second result. In some embodiments, determining the second duty cycle from the first average current and the third average current includes dividing the third average current by the first average current to obtain a first result, subtracting the first result from one to obtain a second result, and multiplying the second result by a cycle period of the periodic signal.

At 214, the method includes averaging the first duty cycle and the second duty cycle to obtain an average duty cycle of the second signal.

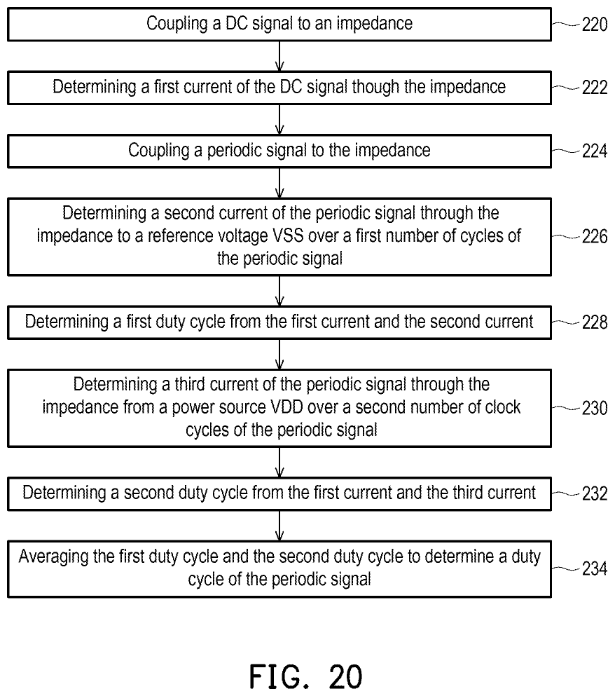

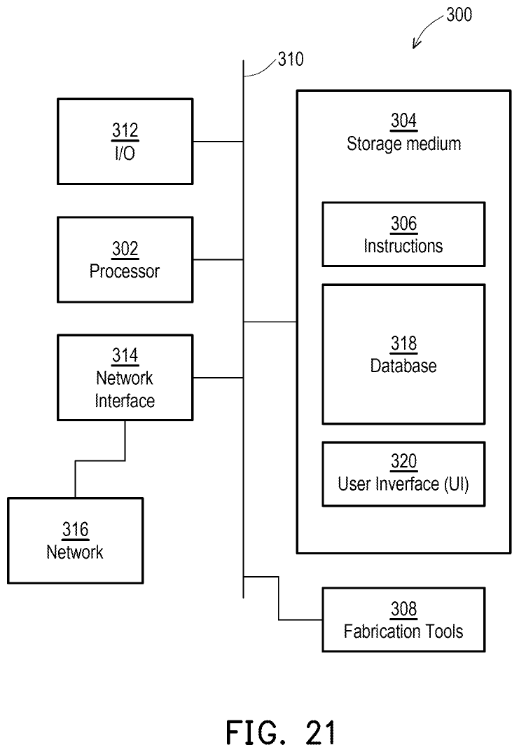

FIG. 20 is a diagram schematically illustrating another method of obtaining an average duty cycle measurement, in accordance with some embodiments. At 220, the method includes coupling a DC signal to an impedance and, at 222, the method includes determining a first current of the DC signal through the impedance.

At 224, the method includes coupling a periodic signal to the impedance and, at 226, the method includes determining a second current of the periodic signal through the impedance to a reference voltage VSS over a first number of cycles of the periodic signal. At 228, the method includes determining a first duty cycle from the first current and the second current. In some embodiments, determining the first duty cycle from the first current and the second current includes dividing the second current by the first current. In some embodiments, determining the first duty cycle from the first current and the second current includes dividing the second current by the first current to obtain a current ratio and multiplying the current ratio by a period of the periodic signal.

At 230, the method includes determining a third current of the periodic signal through the impedance from a power source VDD over a second number of clock cycles of the periodic signal. At 232, the method includes determining a second duty cycle from the first current and the third current. In some embodiments, determining the second duty cycle from the first current and the third current includes dividing the third current by the first current to obtain a first result and subtracting the first result from one to obtain a second result. In some embodiments, determining the second duty cycle from the first current and the third current includes dividing the third current by the first current to obtain a first result, subtracting the first result from one to obtain a second result, and multiplying the second result by a period of the periodic signal.

At 234, the method includes averaging the first duty cycle and the second duty cycle to determine a duty cycle of the periodic signal.

FIG. 21 is a block diagram schematically illustrating an example of a computer system 300 configured to provide the semiconductor devices of the current disclosure, in accordance with some embodiments. Some or all the design, layout, manufacture, testing, and operation of the semiconductor devices, also referred to as semiconductor circuits, can be performed by or with the computer system 300. In some embodiments, the computer system 300 includes an electronic design automation (EDA) system. In some embodiments, the semiconductor devices are ICs.

In some embodiments, the system 300 is a general-purpose computing device including a processor 302 and a non-transitory, computer-readable storage medium 304. The computer-readable storage medium 304 may be encoded with, e.g., store, computer program code such as executable instructions 306. Execution of the instructions 306 by the processor 302 provides (at least in part) a tool that implements a portion or all the functions of the system 300, such as pre-layout simulations, post-layout simulations, routing, rerouting, final layout, testing, and operation of the semiconductor devices. Further, fabrication tools 308 are included to further layout and physically implement the design and manufacture of the semiconductor devices. In some embodiments, execution of the instructions 306 by the processor 302 provides (at least in part) a tool that implements a portion or all the functions of the system 300. In some embodiments, the system 300 includes a commercial router. In some embodiments, the system 300 includes an automatic place and route (APR) system.

The processor 302 is electrically coupled to the computer-readable storage medium 304 by a bus 310 and to an I/O interface 312 by the bus 310. A network interface 314 is also electrically connected to the processor 302 by the bus 310. The network interface 314 is connected to a network 316, so that the processor 302 and the computer-readable storage medium 304 can connect to external elements using the network 316. The processor 302 is configured to execute the computer program code or instructions 306 encoded in the computer-readable storage medium 304 to cause the system 300 to perform a portion or all the functions of the system 300, such as providing the semiconductor devices and methods of the current disclosure and other functions of the system 300. In some embodiments, the processor 302 is a central processing unit (CPU), a multi-processor, a distributed processing system, an application specific integrated circuit (ASIC), and/or a suitable processing unit.

In some embodiments, the computer-readable storage medium 304 is an electronic, magnetic, optical, electromagnetic, infrared, and/or semiconductor system or apparatus or device. For example, the computer-readable storage medium 304 can include a semiconductor or solid-state memory, a magnetic tape, a removable computer diskette, a random-access memory (RAM), a read-only memory (ROM), a rigid magnetic disk, and/or an optical disk. In some embodiments using optical disks, the computer-readable storage medium 304 can include a compact disk read only memory (CD-ROM), a compact disk read/write memory (CD-R/W), and/or a digital video disc (DVD).

In some embodiments, the computer-readable storage medium 304 stores computer program code or instructions 306 configured to cause the system 300 to perform a portion or all the functions of the system 300. In some embodiments, the computer-readable storage medium 304 also stores information which facilitates performing a portion or all the functions of the system 300. In some embodiments, the computer-readable storage medium 304 stores a database 318 that includes one or more of component libraries, digital circuit cell libraries, and databases.

The system 300 includes the I/O interface 312, which is coupled to external circuitry. In some embodiments, the I/O interface 312 includes a keyboard, keypad, mouse, trackball, trackpad, touchscreen, and/or cursor direction keys for communicating information and commands to the processor 302.

The network interface 314 is coupled to the processor 302 and allows the system 300 to communicate with the network 316, to which one or more other computer systems are connected. The network interface 314 can include: wireless network interfaces such as BLUETOOTH, WIFI, WIMAX, GPRS, or WCDMA; or wired network interfaces such as ETHERNET, USB, or IEEE-1364. In some embodiments, a portion or all the functions of the system 300 can be performed in two or more systems that are like system 300.

The system 300 is configured to receive information through the I/O interface 312. The information received through the I/O interface 312 includes one or more of instructions, data, design rules, libraries of components and cells, and/or other parameters for processing by the processor 302. The information is transferred to the processor 302 by the bus 310. Also, the system 300 is configured to receive information related to a user interface (UI) through the I/O interface 312. This UI information can be stored in the computer-readable storage medium 304 as a UI 320.

In some embodiments, a portion or all the functions of the system 300 are implemented via a standalone software application for execution by a processor. In some embodiments, a portion or all the functions of the system 300 are implemented in a software application that is a part of an additional software application. In some embodiments, a portion or all the functions of the system 300 are implemented as a plug-in to a software application. In some embodiments, at least one of the functions of the system 300 is implemented as a software application that is a portion of an EDA tool. In some embodiments, a portion or all the functions of the system 300 are implemented as a software application that is used by the system 300. In some embodiments, a layout diagram is generated using a tool such as VIRTUOSO available from CADENCE DESIGN SYSTEMS, Inc., or another suitable layout generating tool.

In some embodiments, the routing, layouts, and other processes are realized as functions of a program stored in a non-transitory computer readable recording medium. Examples of a non-transitory computer readable recording medium include, but are not limited to, external/removable and/or internal/built-in storage or memory units, e.g., one or more optical disks such as a digital video disc or a digital versatile disc (DVD), a magnetic disk such as a hard disk, a semiconductor memory such as a ROM and a RAM, and a memory card, and the like.

As noted above, embodiments of the system 300 include fabrication tools 308 for implementing the manufacturing processes of the system 300. For example, based on the final layout, photolithographic masks may be generated, which are used to fabricate the semiconductor device by the fabrication tools 308.

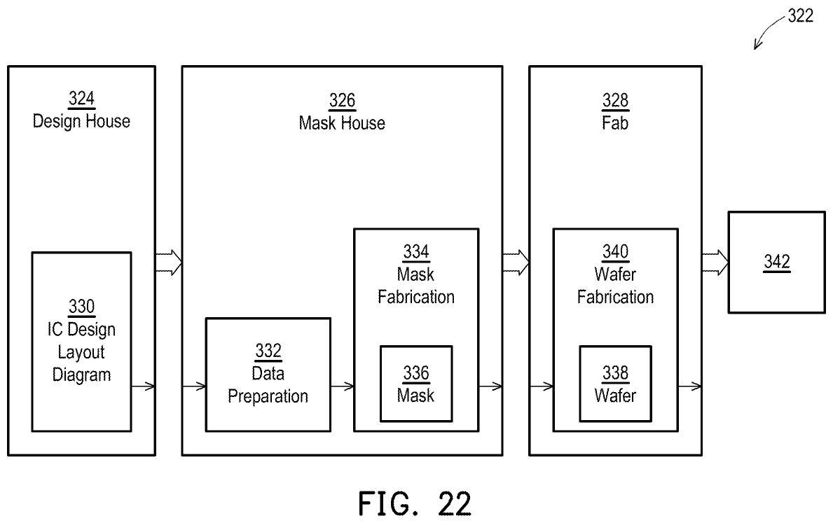

Further aspects of device fabrication are disclosed in conjunction with FIG. 22, which is a block diagram of a semiconductor device manufacturing system 322 and a semiconductor device manufacturing flow associated therewith, in accordance with some embodiments. In some embodiments, based on a layout diagram, one or more semiconductor masks and/or at least one component in a layer of a semiconductor device is fabricated using the manufacturing system 322.

In FIG. 22, the semiconductor device manufacturing system 322 includes entities, such as a design house 324, a mask house 326, and a semiconductor device manufacturer/fabricator (“Fab”) 328, that interact with one another in the design, development, and manufacturing cycles and/or services related to manufacturing a semiconductor device, such as the semiconductor devices described herein. The entities in the system 322 are connected by a communications network. In some embodiments, the communications network is a single network. In some embodiments, the communications network is a variety of different networks, such as an intranet and the internet. The communications network includes wired and/or wireless communication channels. Each entity interacts with one or more of the other entities and provides services to and/or receives services from one or more of the other entities. In some embodiments, two or more of the design house 324, the mask house 326, and the semiconductor device fab 328 are owned by a single larger company. In some embodiments, two or more of the design house 324, the mask house 326, and the semiconductor device fab 328 coexist in a common facility and use common resources.

The design house (or design team) 324 generates a semiconductor device design layout diagram 330. The semiconductor device design layout diagram 330 includes various geometrical patterns, or semiconductor device layout diagrams designed for a semiconductor device. The geometrical patterns correspond to patterns of metal, oxide, or semiconductor layers that make up the various components of the semiconductor structures to be fabricated. The various layers combine to form various semiconductor device features. For example, a portion of the semiconductor device design layout diagram 330 includes various semiconductor device features, such as diagonal vias, active areas or regions, gate electrodes, sources, drains, metal lines, local vias, and openings for bond pads, to be formed in a semiconductor substrate (such as a silicon wafer) and in various material layers disposed on the semiconductor substrate. The design house 324 implements a design procedure to form a semiconductor device design layout diagram 330. The semiconductor device design layout diagram 330 is presented in one or more data files having information of the geometrical patterns. For example, semiconductor device design layout diagram 330 can be expressed in a GDSII file format or DFII file format. In some embodiments, the design procedure includes one or more of analog circuit design, digital circuit design, logic circuit design, standard cell circuit design, power distribution network (PDN) design including power via design, supply voltage track design, reference voltage track design, place and route routines, and physical layout designs.

The mask house 326 includes data preparation 332 and mask fabrication 334. The mask house 326 uses the semiconductor device design layout diagram 330 to manufacture one or more masks 336 to be used for fabricating the various layers of the semiconductor device or semiconductor structure. The mask house 326 performs mask data preparation 332, where the semiconductor device design layout diagram 330 is translated into a representative data file (RDF). The mask data preparation 332 provides the RDF to the mask fabrication 334. The mask fabrication 334 includes a mask writer that converts the RDF to an image on a substrate, such as a mask (reticle) 336 or a semiconductor wafer 338. The design layout diagram 330 is manipulated by the mask data preparation 332 to comply with characteristics of the mask writer and/or criteria of the semiconductor device fab 328. In FIG. 22, the mask data preparation 332 and the mask fabrication 334 are illustrated as separate elements. In some embodiments, the mask data preparation 332 and the mask fabrication 334 can be collectively referred to as mask data preparation.

In some embodiments, the mask data preparation 332 includes an optical proximity correction (OPC) which uses lithography enhancement techniques to compensate for image errors, such as those that can arise from diffraction, interference, other process effects and the like. The OPC adjusts the semiconductor device design layout diagram 330. In some embodiments, the mask data preparation 332 includes further resolution enhancement techniques (RET), such as off-axis illumination, sub-resolution assist features, phase-shifting masks, other suitable techniques, and the like or combinations thereof. In some embodiments, inverse lithography technology (ILT) is also used, which treats OPC as an inverse imaging problem.

In some embodiments, the mask data preparation 332 includes a mask rule checker (MRC) that checks the semiconductor device design layout diagram 330 that has undergone processes in OPC with a set of mask creation rules which contain certain geometric and/or connectivity restrictions to ensure sufficient margins, to account for variability in semiconductor manufacturing processes, and the like. In some embodiments, the MRC modifies the semiconductor device design layout diagram 330 to compensate for limitations during the mask fabrication 334, which may undo part of the modifications performed by OPC to meet mask creation rules.

In some embodiments, the mask data preparation 332 includes lithography process checking (LPC) that simulates processing that will be implemented by the semiconductor device fab 328. LPC simulates this processing based on the semiconductor device design layout diagram 330 to create a simulated manufactured device. The processing parameters in LPC simulation can include parameters associated with various processes of the semiconductor device manufacturing cycle, parameters associated with tools used for manufacturing the semiconductor device, and/or other aspects of the manufacturing process. LPC considers various factors, such as aerial image contrast, depth of focus (“DOF”), mask error enhancement factor (“MEEF”), other suitable factors, and the like or combinations thereof. In some embodiments, after a simulated manufactured device has been created by LPC, if the simulated device is not close enough in shape to satisfy design rules, OPC and/or MRC are be repeated to further refine the semiconductor device design layout diagram 330.

The above description of mask data preparation 332 has been simplified for the purposes of clarity. In some embodiments, data preparation 332 includes additional features such as a logic operation (LOP) to modify the semiconductor device design layout diagram 330 according to manufacturing rules. Additionally, the processes applied to the semiconductor device design layout diagram 330 during data preparation 332 may be executed in a variety of different orders.

After the mask data preparation 332 and during the mask fabrication 334, a mask 336 or a group of masks 336 are fabricated based on the modified semiconductor device design layout diagram 330. In some embodiments, the mask fabrication 334 includes performing one or more lithographic exposures based on the semiconductor device design layout diagram 330. In some embodiments, an electron-beam (e-beam) or a mechanism of multiple e-beams is used to form a pattern on a mask (photomask or reticle) 336 based on the modified semiconductor device design layout diagram 330. The mask 336 can be formed in various technologies. In some embodiments, the mask 336 is formed using binary technology. In some embodiments, a mask pattern includes opaque regions and transparent regions. A radiation beam, such as an ultraviolet (UV) beam, used to expose the image sensitive material layer (e.g., photoresist) which has been coated on a wafer, is blocked by the opaque region, and transmits through the transparent regions. In one example, a binary mask version of the mask 336 includes a transparent substrate (e.g., fused quartz) and an opaque material (e.g., chromium) coated in the opaque regions of the binary mask. In another example, the mask 336 is formed using a phase shift technology. In a phase shift mask (PSM) version of the mask 336, various features in the pattern formed on the phase shift mask are configured to have proper phase difference to enhance the resolution and imaging quality. In various examples, the phase shift mask can be attenuated PSM or alternating PSM. The mask(s) generated by the mask fabrication 334 is used in a variety of processes. For example, such a mask(s) is used in an ion implantation process to form various doped regions in the semiconductor wafer 338, in an etching process to form various etching regions in the semiconductor wafer 338, and/or in other suitable processes.

The semiconductor device fab 328 includes wafer fabrication 340. The semiconductor device fab 328 is a semiconductor device fabrication business that includes one or more manufacturing facilities for the fabrication of a variety of different semiconductor device products. In some embodiments, the semiconductor device fab 328 is a semiconductor foundry. For example, there may be a manufacturing facility for the front end of line (FEOL) fabrication of a plurality of semiconductor device products, while a second manufacturing facility may provide the back end of line (BEOL) fabrication for the interconnection and packaging of the semiconductor device products, and a third manufacturing facility may provide other services for the foundry business.

The semiconductor device fab 328 uses the mask(s) 336 fabricated by the mask house 326 to fabricate the semiconductor structures or semiconductor devices 342 of the current disclosure. Thus, the semiconductor device fab 328 at least indirectly uses the semiconductor device design layout diagram 330 to fabricate the semiconductor structures or semiconductor devices 342 of the current disclosure. Also, the semiconductor wafer 338 includes a silicon substrate or other proper substrate having material layers formed thereon, and the semiconductor wafer 338 further includes one or more of various doped regions, dielectric features, multilevel interconnects, and the like (formed at subsequent manufacturing steps). In some embodiments, the semiconductor wafer 338 is fabricated by the semiconductor device fab 328 using the mask(s) 336 to form the semiconductor structures or semiconductor devices 342 of the current disclosure. In some embodiments, the semiconductor device fabrication includes performing one or more lithographic exposures based at least indirectly on the semiconductor device design layout diagram 330.

Disclosed embodiments include systems and methods of duty cycle characterization that use TCC. To reduce error in the duty cycle measurements, a first duty cycle is determined based on the interval of time that the periodic signal is at a high voltage and a second duty cycle is determined based on the interval of time that the periodic signal is at a low voltage. The first duty cycle and the second duty cycle are averaged to provide a duty cycle measurement that has a smaller error. For example, if the non-linear portion of the periodic signal is more favorable to the high voltage or “1” region and less favorable to the low voltage or “0” region, then averaging the first and second duty cycles provides a duty cycle measurement with a smaller error percentage, such as closer to 0%.

Disclosed embodiments provide a method that includes coupling a first signal to an impedance and determining a first average current of the first signal through the impedance over a first time, where the first average current corresponds to a duty cycle of the first signal. The method further includes coupling a second signal to the impedance and determining a second average current of the second signal through the impedance over a second time, the second average current corresponding to a first duty cycle of the second signal, and determining the first duty cycle from the first average current and the second average current. The method further includes determining a third average current of the second signal through the impedance over a third time, the third average current corresponding to a second duty cycle of the second signal, and determining the second duty cycle from the first average current and the third average current. Then, the method includes averaging the first duty cycle and the second duty cycle to obtain an average duty cycle measurement of the second signal.

Advantages of the methods and systems disclosed herein include improved accuracy of the duty cycle measurement and improved speed in determining the duty cycle measurement.

In accordance with some embodiments, a method includes coupling a first signal to an impedance; determining a first average current of the first signal through the impedance over a first time, the first average current corresponding to a duty cycle of the first signal; coupling a second signal to the impedance; determining a second average current of the second signal through the impedance over a second time, the second average current corresponding to a first duty cycle of the second signal; determining the first duty cycle from the first average current and the second average current; determining a third average current of the second signal through the impedance over a third time, the third average current corresponding to a second duty cycle of the second signal; determining the second duty cycle from the first average current and the third average current; and averaging the first duty cycle and the second duty cycle to obtain an average duty cycle of the second signal.

In accordance with further embodiments, a method includes coupling a DC signal to an impedance; determining a first current of the DC signal through the impedance; coupling a periodic signal to the impedance; determining a second current of the periodic signal through the impedance to a reference voltage VSS over a first number of cycles of the periodic signal; determining a first duty cycle from the first current and the second current; determining a third current of the periodic signal through the impedance from a power source VDD over a second number of clock cycles of the periodic signal; determining a second duty cycle from the first current and the third current; and averaging the first duty cycle and the second duty cycle to determine a duty cycle of the periodic signal.

In accordance with still further disclosed aspects, a system includes a logic circuit, an impedance, and a measurement circuit. The logic circuit has at least one input configured to receive a first signal and a second signal and an output configured to provide a first output signal that corresponds to the first signal and a second output signal that corresponds to the second signal. The impedance is connected to the output and configured to receive the first output signal and the second output signal. The measurement circuit is connected to the impedance and configured to determine a first average current through the impedance based on the first output signal, a second average current through the impedance to a reference voltage based on the second signal, and a third average current through the impedance from a power source based on the second signal.

This disclosure outlines various embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
coupling a first signal to an impedance;
determining a first average current of the first signal through the impedance over a first time, the first average current corresponding to a duty cycle of the first signal;
coupling a second signal to the impedance;
determining a second average current of the second signal through the impedance over a second time, the second average current corresponding to a first duty cycle of the second signal;
determining the first duty cycle from the first average current and the second average current;
determining a third average current of the second signal through the impedance over a third time, the third average current corresponding to a second duty cycle of the second signal;
determining the second duty cycle from the first average current and the third average current; and
averaging the first duty cycle and the second duty cycle to obtain an average duty cycle of the second signal.

2. The method of claim 1, wherein coupling the first signal to the impedance includes coupling a DC signal to the impedance.

3. The method of claim 1, wherein coupling the second signal to the impedance includes coupling a periodic signal to the impedance.

4. The method of claim 3, wherein determining the second average current of the second signal through the impedance includes determining the second average current of the second signal through the impedance to a reference voltage VSS over the second time.

5. The method of claim 4, wherein determining the first duty cycle from the first average current and the second average current includes dividing the second average current by the first average current.

6. The method of claim 4, wherein determining the first duty cycle from the first average current and the second average current includes dividing the second average current by the first average current to obtain a current ratio and multiplying the current ratio by a cycle period of the periodic signal.

7. The method of claim 3, wherein determining the third average current of the second signal through the impedance includes determining the third average current of the second signal through the impedance from a power source VDD over the third time.

8. The method of claim 7, wherein determining the second duty cycle from the first average current and the third average current includes dividing the third average current by the first average current to obtain a first result and subtracting the first result from one to obtain a second result.

9. The method of claim 7, wherein determining the second duty cycle from the first average current and the third average current includes dividing the third average current by the first average current to obtain a first result, subtracting the first result from one to obtain a second result, and multiplying the second result by a cycle period of the periodic signal.

10. The method of claim 1, wherein the first time is equal to each of the second time and the third time.

11. The method of claim 1, wherein the second time is equal to the third time.

12. A method, comprising:
coupling a DC signal to an impedance;
determining a first current of the DC signal through the impedance;
coupling a periodic signal to the impedance;
determining a second current of the periodic signal through the impedance to a reference voltage VSS over a first number of cycles of the periodic signal;
determining a first duty cycle from the first current and the second current;
determining a third current of the periodic signal through the impedance from a power source VDD over a second number of clock cycles of the periodic signal;
determining a second duty cycle from the first current and the third current; and
averaging the first duty cycle and the second duty cycle to determine a duty cycle of the periodic signal.

13. The method of claim 12, wherein determining the first duty cycle from the first current and the second current includes dividing the second current by the first current.

14. The method of claim 12, wherein determining the first duty cycle from the first current and the second current includes dividing the second current by the first current to obtain a current ratio and multiplying the current ratio by a period of the periodic signal.

15. The method of claim 12, wherein determining the second duty cycle from the first current and the third current includes dividing the third current by the first current to obtain a first result and subtracting the first result from one to obtain a second result.

16. The method of claim 12, wherein determining the second duty cycle from the first current and the third current includes dividing the third current by the first current to obtain a first result, subtracting the first result from one to obtain a second result, and multiplying the second result by a period of the periodic signal.

17. A system, comprising:
a logic circuit having at least one input configured to receive a first signal and a second signal and an output configured to provide a first output signal that corresponds to the first signal and a second output signal that corresponds to the second signal;
an impedance connected to the output and configured to receive the first output signal and the second output signal; and
a measurement circuit connected to the impedance and configured to determine a first average current through the impedance based on the first output signal, a second average current through the impedance to a reference voltage based on the second signal, and a third average current through the impedance from a power source based on the second signal.

18. The system of claim 17, wherein the measurement circuit is configured to determine a first duty cycle of the second signal from the first average current and the second average current, a second duty cycle of the second signal from the first average current and the third average current, and a duty cycle of the second signal based on an average of the first duty cycle and the second duty cycle.

19. The system of claim 18, wherein the measurement circuit is configured to determine the first duty cycle from the first average current and the second average current by dividing the second average current by the first average current.

20. The system of claim 18, wherein the measurement circuit is configured to determine the second duty cycle from the first average current and the third average current by dividing the third average current by the first average current to obtain a first result and subtracting the first result from one to obtain a second result.
